(19) United States
(12) Patent Application Publication
(10) Pub. No.: US 2012/0286324 A1
(43) Pub. Date: Nov. 15, 2012

(54) MANUFACTURING METHOD FOR INSULATED-GATE BIPOLAR TRANSITOR AND DEVICE USING THE SAME

(75) Inventor: Nam-Young Lee, Hwaseong-si (KR)

(73) Assignee: SAMSUNG ELECTRONICS CO., LTD., Suwon-si (KR)

(21) Appl. No.: 13/440,057

(22) Filed: Apr. 5, 2012

(30) Foreign Application Priority Data
May 13, 2011 (KR) 10-2011-0045282

(51) Int. Cl. H01L 29/732; H01L 21/331

(52) U.S. Cl. 257/139; 438/138; 257/E29.198; 257/E21.383

(57) ABSTRACT

Provided is a manufacturing method for an insulated-gate bipolar transistor (IGBT). The manufacturing method includes providing a structure including a substrate, a first conductivity type epitaxial layer formed on the substrate, a gate electrode formed on a first surface of the epitaxial layer, a second conductivity type body region formed at opposite sides of the gate electrode in the first surface of the epitaxial layer, and a first conductivity type source region formed within the body region; removing a portion of the substrate by back grinding; and removing the other portion of the substrate by etching until the second surface of the epitaxial layer is exposed.

### CROSS-REFERENCE TO RELATED APPLICATION

This application claims priority from Korean Patent Application No. 10-2011-0045282 filed on May 13, 2011 in the Korean Intellectual Property Office, and all the benefits accruing therefrom under 35 U.S.C. 119, the contents of which in its entirety are herein incorporated by reference.

### BACKGROUND

1. Field

Embodiments of the present inventive concepts relate to a manufacturing method for an insulated-gate bipolar transistor, and, more particularly, to a manufacturing method that allows for precise adjustment of the thickness of an insulated-gate bipolar transistor.

2. Description of the Related Art

An insulated-gate bipolar transistor (IGBT) is a power semiconductor device that may be used in a high-efficiency, high-speed power systems, particularly for systems operating in a high-voltage region over 300 V. An IGBT typically offers higher output voltage characteristics than a bipolar transistor and faster switching characteristics than an MOSFET. An IGBT may switch in excess of 300V at speeds as high as approximately 100 kHz, for example.

### SUMMARY

Embodiments provide a manufacturing method for an insulated-gate bipolar transistor (IGBT). The method may be used to delicately adjust the thickness of a substrate associated with an insulated-gate bipolar transistor while removing the substrate, thereby improving the switching speed of the IGBT.

According to an aspect of inventive concepts, there is provided a manufacturing method for an IGBT, the manufacturing method including providing a structure including a substrate, a first conductivity type epitaxial layer formed on the substrate, a gate electrode formed on one surface, also referred to herein as a first surface, of the epitaxial layer, a second conductivity type body region formed at opposite sides of the gate electrode in the first surface of the epitaxial layer, and a first conductivity type source region formed within the body region, removing a portion of the substrate by back grinding, and removing the other portion of the substrate by etching until the other surface, also referred to herein as the second surface, of the epitaxial layer is exposed.

According to another aspect of inventive concepts, there is provided a manufacturing method for an IGBT, the manufacturing method including forming a first conductivity type epitaxial layer on a substrate by epitaxial growth, forming a second conductivity type body region within one surface of the epitaxial layer, forming a first conductivity type source region and a second conductivity type emitter region within the body region, forming a gate electrode on the one surface of the epitaxial layer, removing the substrate until the other surface of the epitaxial layer is exposed, and forming a first conductivity type first doping region and a second conductivity type second doping region within the other surface of the epitaxial layer.

According to another aspect of inventive concepts, a manufacturing method for producing insulated gate bipolar transistors includes the steps of providing a structure including a substrate; forming a first conductivity type epitaxial layer on the substrate; forming a gate electrode on a first surface of the epitaxial layer; forming a second conductivity type body region at opposite sides of the gate electrode in the first surface; forming a first conductivity type source region within the body region; removing a portion of the substrate by back grinding; and removing the other portion of the substrate by etching until a second surface of the epitaxial layer is exposed.

According to another aspect of inventive concepts an IGBT manufacturing method includes forming a first conductivity type first doping region and a second conductivity type second doping region within the second surface of the epitaxial layer.

According to another aspect of inventive concepts an IGBT manufacturing method includes forming a first conductivity type buffer layer having a higher doping density than the epitaxial layer within the epitaxial layer before forming the first doping region and the second doping region.

According to another aspect of inventive concepts an IGBT manufacturing method includes forming a first conductivity type barrier layer having a higher doping density than the epitaxial layer under the body region within the epitaxial layer.

According to another aspect of inventive concepts an IGBT manufacturing method forming a second conductivity type emitter region within the body region, wherein the emitter region is electrically connected to the same potential as the source region.

According to another aspect of inventive concepts an IGBT manufacturing method includes supplying a substrate is of a first conductivity type and having a higher doping density than the epitaxial layer.

According to another aspect of inventive concepts an IGBT manufacturing method includes supplying a substrate of a second conductivity type.

According to another aspect of inventive concepts an IGBT manufacturing method includes forming an insulation layer on the body region, the source region, and the gate electrode; forming a first interconnection connected to the body region and the source region on the insulation layer; forming a first conductivity type first doping region and a second conductivity type second doping region within the second surface of the epitaxial layer; and forming a collector electrode on the first doping region and the second doping region.

According to another aspect of inventive concepts an IGBT manufacturing method includes forming an insulation layer on the body region, the source region, and the gate electrode; forming a support wafer on the insulation layer; and removing the support wafer after the removing of the other portion of the substrate before removing the substrate.

According to another aspect of inventive concepts an IGBT manufacturing method includes performing chemical mechanical polishing on the second surface of the epitaxial layer after removing the other portion of the substrate.

According to another aspect of inventive concepts an IGBT manufacturing method includes forming a plurality of trenches penetrating the body region and the source region and extending to the inside of the epitaxial layer; forming a gate insulation layer on the inner sidewall of each of the trenches; and forming a gate electrode within each of the trenches.

According to another aspect of inventive concepts an IGBT manufacturing method includes etching using an etchant having an etch ratio of the substrate to the epitaxial layer of at least 20:1.

According to another aspect of inventive concepts an IGBT manufacturing method includes forming a first conductivity type epitaxial layer on a substrate by epitaxial growth; forming a second conductivity type body region within a first surface of the epitaxial layer; forming a first conductivity type source region and a second conductivity type emitter region within the body region; forming a gate electrode on a first surface of the epitaxial layer; removing the substrate until the second surface of the epitaxial layer is exposed; and forming a first conductivity type first doping region and a second conductivity type second doping region within the second surface of the epitaxial layer.

According to another aspect of inventive concepts an IGBT manufacturing method includes removing a portion of the substrate by back grinding.

According to another aspect of inventive concepts an IGBT manufacturing method includes removing a remaining portion of the substrate by etching.

According to another aspect of inventive concepts an insulated-gate bipolar transistor (IGBT) includes an epitaxial layer of a first conductivity type; an insulated gate electrode formed on a first surface of the epitaxial layer; body regions of a second conductivity type formed in the first surface of the epitaxial layer on either side of the insulated gate electrode; source regions of the first conductivity type formed in the body regions adjacent to either side of the insulated gate electrode; emitter regions of the second conductivity type formed in the body regions opposite source regions from the insulated gate electrode; and a collector formed on a second surface of the epitaxial layer with no intervening substrate.

According to another aspect of an IGBT in accordance with principles of inventive concepts an IGBT includes a buffer layer situated between the collector and the epitaxial layer.

According to another aspect of an IGBT in accordance with principles of inventive concepts an IGBT includes a diode structure formed between the collector and the epitaxial layer.

According to another aspect of an IGBT in accordance with principles of inventive concepts an IGBT includes a diode implanted in the epitaxial layer.

According to another aspect of an IGBT in accordance with principles of inventive concepts an IGBT includes a collector implanted in the epitaxial layer.

The above and other objects of inventive concepts will be described in or be apparent from the following description of the preferred embodiments.

### BRIEF DESCRIPTION OF THE DRAWINGS

The above and other features and advantages of inventive concepts will become more apparent by describing in detail preferred embodiments thereof with reference to the attached drawings in which:

FIGS. 1 to 14 are cross-sectional views illustrating process steps of a manufacturing method of an insulated-gate bipolar transistor (IGBT) according to a first embodiment of inventive concepts;

FIGS. 15 to 21 are cross-sectional views illustrating process steps of a manufacturing method of an IGBT according to a second embodiment of inventive concepts;

FIGS. 15 to 21 are cross-sectional views illustrating process steps of a manufacturing method of an IGBT according to a second embodiment of inventive concepts;

FIG. 22 is a cross-sectional view of an IGBT according to a third embodiment of inventive concepts;

FIGS. 23 to 29 are cross-sectional views illustrating process steps of a manufacturing method of an IGBT according to a fourth embodiment of inventive concepts;

FIG. 30 is a cross-sectional view of an IGBT according to a fifth embodiment of inventive concepts.

### DETAILED DESCRIPTION OF THE EMBODIMENTS

Exemplary embodiments of the inventive concepts will now be described more fully with reference to the accompanying drawings, in which exemplary embodiments of the inventive concept are shown. Exemplary embodiments of the inventive concept may, however, be embodied in many different forms and should not be construed as limited to the embodiments set forth herein; rather, these exemplary embodiments of the inventive concept are provided so that this description will be thorough and complete, and will fully convey the concept of exemplary embodiments of the inventive concept to those of ordinary skill in the art. In the drawings, the thicknesses of layers and regions are exaggerated for clarity. Like reference numerals in the drawings denote like elements, and thus their description will be omitted.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated, for example, 90 degrees or at other orientations) and the spatially relative descriptors used herein interpreted accordingly.

The terminology used herein is for the purpose of describing particular exemplary embodiments of the inventive concept only and is not intended to be limiting of the inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the inventive concept are described herein with reference to cross-sectional illustrations that are schematic illustrations of idealized exemplary embodiments of the inventive concept (and intermediate structures). As such, variations from the shapes of the illustrations as a result, for example, of manufacturing techniques and/or tolerances, are to be expected. Thus, exemplary embodiments of the inventive concept should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

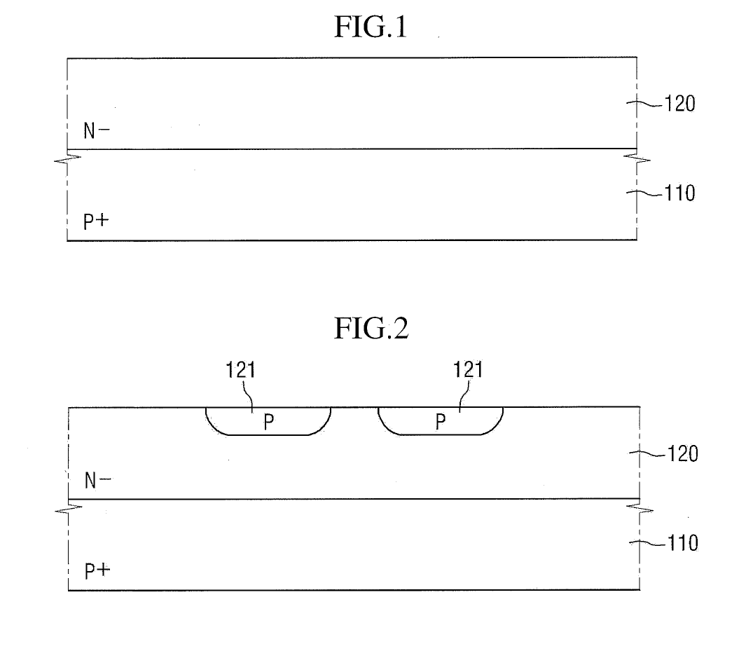

Hereinafter, exemplary embodiments of inventive concepts will be described with reference to the accompanying drawings. A manufacturing method of an IGBT according to a first embodiment of inventive concepts will now be described with reference to FIGS. 1 to 14. FIGS. 1 to 14 are cross-sectional views illustrating process steps of an exemplary manufacturing method of an IGBT in accordance with principles of inventive concepts.

Referring first to FIG. 1, an epitaxial layer 120 of a first conductivity type (e.g., N−) may be formed on a substrate 110. Substrate 110 may be of a second conductivity type (e.g., P+), for example. Alternatively, substrate 110 may be of the same conductivity type as epitaxial layer 120, but with a higher doping density (e.g., N+). In an exemplary embodiment in accordance with the principles of inventive concepts, a doping density ratio of substrate 110 to epitaxial layer 120 may be 10:1 or higher. For example, substrate 110 may have a doping density of 10¹⁵/cm² or higher. The term “doping density” refers to a dose of impurities doped (implanted) into a region.

In exemplary embodiments in accordance with principles of inventive concepts, substrate 110 may include, for example, a silicon semiconductor substrate, a gallium arsenic semiconductor substrate, a silicon germanium semiconductor substrate, a ceramic semiconductor substrate, a quartz semiconductor substrate, a glass semiconductor substrate (for use, for example, in a display), or other materials, for example.

Epitaxial layer 120 may be formed on substrate 110 by epitaxial growth. For example, epitaxial layer 120 may be formed by solid phase epitaxy, vapor phase epitaxy, molecular beam epitaxy, or the like. In exemplary embodiments in accordance with principles of inventive concepts, epitaxial layer 120 may be formed by simultaneously implanting a silicon source gas and a source gas of N-type dopants (for example, phosphorous (P), arsenic (As), or antimony (Sb)), onto the substrate 110, followed by epitaxial growth. The dose of epitaxial layer 120 may be in a range of from 10¹¹ to 10¹⁵/cm², for example. The thickness and dose of the epitaxial layer 120 may be adjusted to accommodate the voltage applied to a region in which the IGBT is to be used.

Referring to FIG. 2, a body region 121 of a second conductivity type (e.g., P) may be formed within epitaxial layer 120. In an exemplary embodiment in accordance with principles of inventive concepts, a mask pattern defining a body region 121 may be formed on a first surface of epitaxial layer 120. P-type dopants, such as B, BF₂ or In, may then be implanted into a first surface of epitaxial layer 120 in regions exposed by the mask pattern. The mask pattern may then be removed, thereby forming body region 121. In an exemplary embodiment in accordance with principles of inventive concepts, after implanting P-type dopants, annealing may be performed to diffuse the dopants. In this exemplary embodiment, body region 121 has a different conductivity type than epitaxial layer 120. Body region 121 may have the same conductivity type as the substrate 110, for example. In an exemplary embodiment in accordance with principles of inventive concepts, the doping density of the body region 121 may be lower than that of the substrate 110.

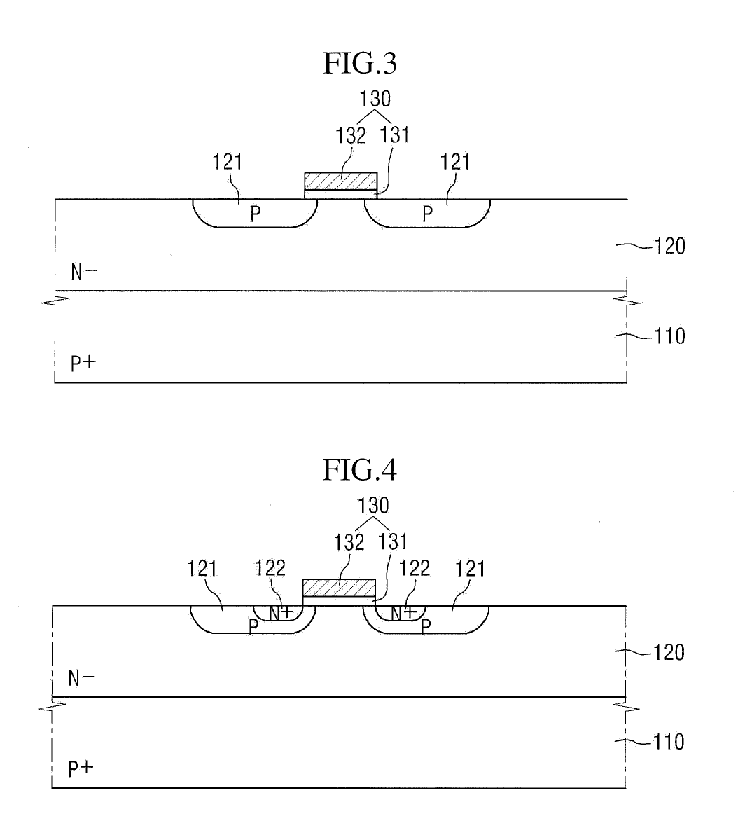

Referring to FIG. 3, a gate pattern 130 is formed on the first surface of epitaxial layer 120. In an exemplary embodiment in accordance with principles of inventive concepts, an insulation layer for a gate insulation layer and a conductive layer for a gate electrode may be sequentially deposited on a surface of epitaxial layer 120, and patterned, thereby forming gate pattern 130 including a gate insulation layer 131 and a gate electrode 132. The gate insulation layer 131 may be formed of a silicon oxide layer (SiOₓ), silicon oxynitride layer (SiON), titanium oxide layer (TiOₓ), tantalum oxide layer (TaOₓ), or a stacked layer having these layers sequentially stacked, for example. Gate electrode 132 may be a conductor formed of an n-type or p-type dopant-doped polysilicon layer, a metal layer, a metal silicide layer, or metal nitride layer, for example. Gate electrode 132 may have a stacked structure having two or more layers. The metal included in gate electrode 132 may include, for example, tungsten (W), cobalt (Co), nickel (Ni), titanium (Ti), or tantalum (Ta), for example. Gate insulation layer 131 and gate electrode 132 may be formed by chemical vapor deposition or sputtering, for example.

In accordance with principles of inventive concepts, a self-aligned process may be employed to form body region 121. For example, body region 121 may be formed after forming the gate pattern 130 by implanting P-type dopants using gate 130 as an impurity mask. Because gate 130 acts as a mask when implanting the dopants, body region 121 is self-aligned on both sides of gate 130. Self-aligning in such a manner obviates the need for forming a mask pattern and ensures alignment of gate 130 and body region 121.

Gate pattern 130 may be formed to overlap a portion of the body region 121. In an exemplary embodiment in accordance with principles of inventive concepts, a channel may be formed under gate pattern 130 overlapping body region 121.

Referring to FIG. 4, a source region 122 of a first conductivity type (e.g., N+) may be formed at either side of gate pattern 130. In an exemplary embodiment in accordance with principles of inventive concepts, a mask pattern, or, simply, mask (not shown) is formed on a surface of epitaxial layer 120, N-type dopants are implanted into regions of epitaxial layer 120 exposed by the mask, then the mask is removed to form source region 122.

In an exemplary embodiment, source region 122 is formed within body region 121 and has a different conductivity type from body region 121. Source region 122 may have the same conductivity type as epitaxial layer 120, for example, and may have a higher doping density than epitaxial layer 120.

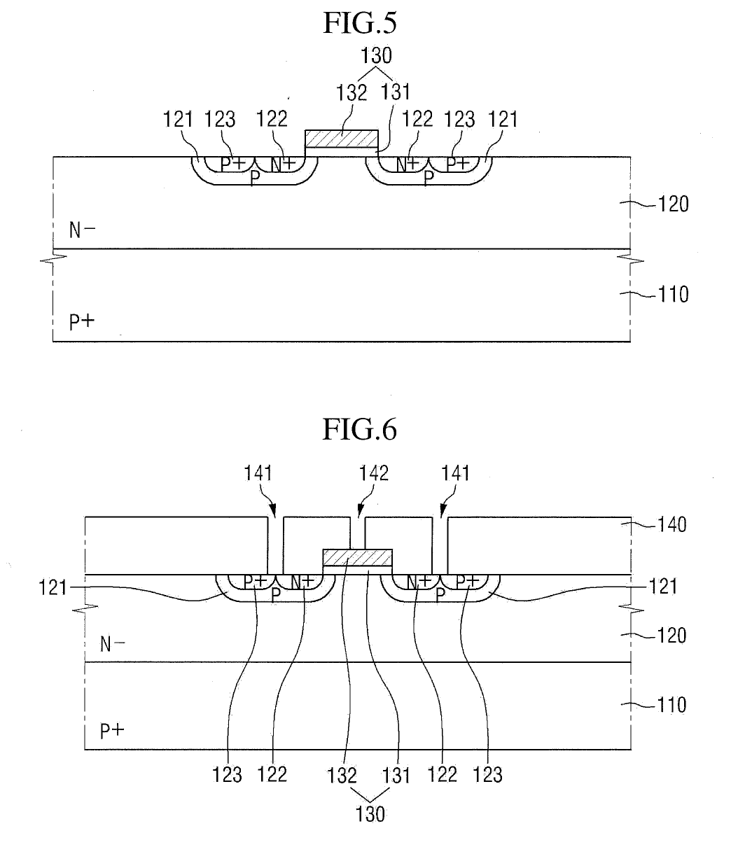

Referring to FIG. 5, an emitter region 123 of a second conductivity type (e.g., P+) may be formed in body region 121. In an exemplary embodiment in accordance with principles of inventive concepts, a mask pattern may be formed on a surface of epitaxial layer 120, P-type dopants may then be implanted into regions of epitaxial layer 120 exposed by the mask, thereby forming emitter region 123. The mask pattern may then be removed. Emitter region 123 may be formed at one side of source region 122 or may contact one side of the source region 122. In the exemplary embodiment in accordance with principles of inventive concepts of FIG. 5, emitter region 123 contacts source region 122. Emitter region 123 may have the same conductivity type as body region 122. In an exemplary embodiment in accordance with principles of inventive concepts, emitter region 123 may have a higher doping density than body region 121.

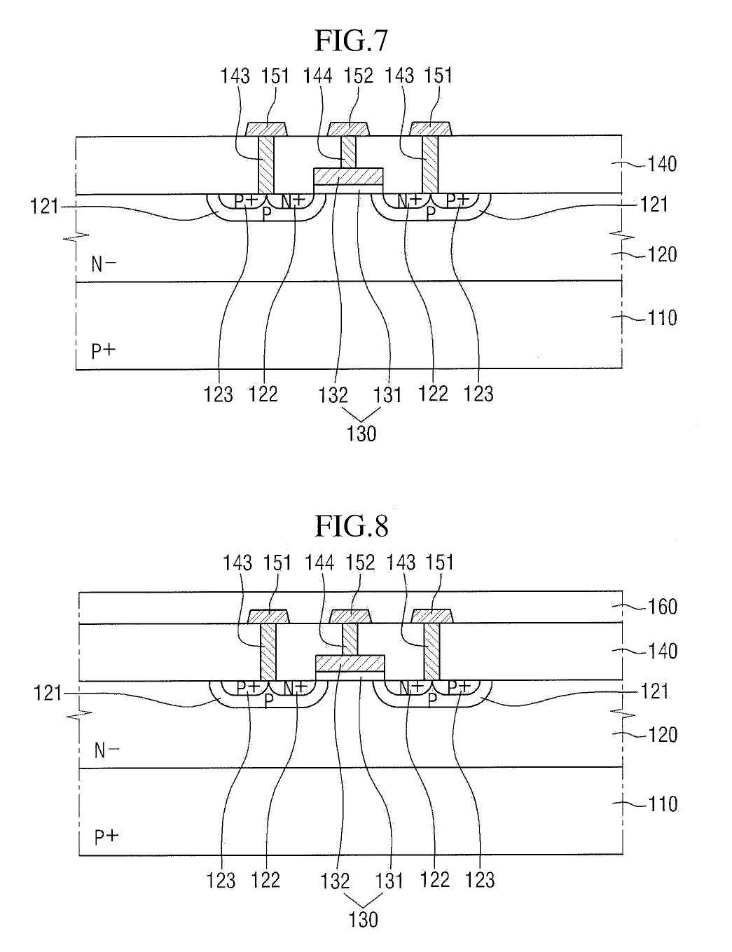

Referring to FIGS. 6 and 7, an insulation layer 140 may be formed over epitaxial layer 120 and gate 130. Then, a first interconnection 151 and a second interconnection 152 may be formed on insulation layer 140.

In an exemplary embodiment in accordance with principles of inventive concepts, insulation layer 140 may be formed over epitaxial layer 120, including body region 121, source region 122 and emitter region 123. Insulation layer 140 may also formed over gate pattern 130 in such an embodiment. First contact hole 141 and second contact hole 142 may be formed by forming a mask pattern defining first contact hole 141 and second contact hole 142 may be on insulation layer 140, then etching areas of insulation layer 140 exposed by the mask pattern. First contact hole 141 and a second contact hole 142 may then be filled with a conductive material to form a first contact 143 and a second contact 144. A conductive layer may then be deposited on insulation layer 140 and patterned to form first interconnection 151 and second interconnection 152.

Insulation layer 140 may be formed of a silicon oxide layer, a silicon nitride layer or a stacked layer thereof, for example. Gate electrode 132 and first interconnection 151 may be insulated from each other by insulation layer 140.

In exemplary embodiments in accordance with principles of inventive concepts, first contact hole 141 simultaneously exposes a portion of source region 122 and a portion of emitter region 123. First interconnection 151 is, therefore, electrically connected simultaneously to source region 122 and emitter region 123 through the first contact 143, and, as a result, the same voltage may be simultaneously applied to source region 122 and emitter region 123 by first interconnection 151.

Second contact hole 142 exposes a portion of gate electrode 132 and second interconnection 152 is electrically connected to gate electrode 132 through second contact 144, thereby enabling the application of a voltage to gate electrode 132 through second interconnection 152.

Referring to FIG. 8, a passivation layer 160 may be formed on insulation layer 140, first interconnection 151 and second interconnection 152. Passivation layer 160 planarizes a top surface of the IGBT according to an exemplary embodiment in accordance with principles of inventive concepts. Passivation layer 160 may be formed of a silicon oxide layer, a silicon nitride layer or a stacked layer thereof, for example.

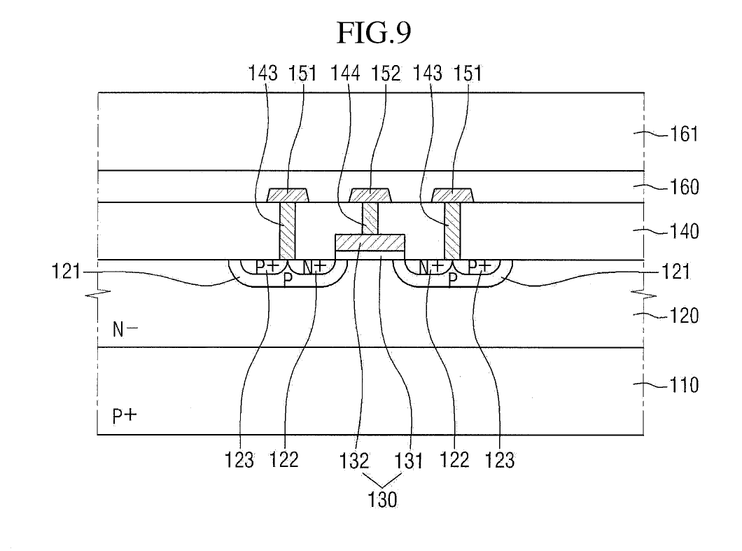

In an exemplary embodiment in accordance with principles of inventive concepts, in FIG. 9 a sustain wafer (also referred to herein as a support wafer) 161 is formed on the passivation layer 160. Sustain wafer 161 sustains and protects the IGBT in a subsequent process and may be made of any material that can sustain and protect the IGBT.

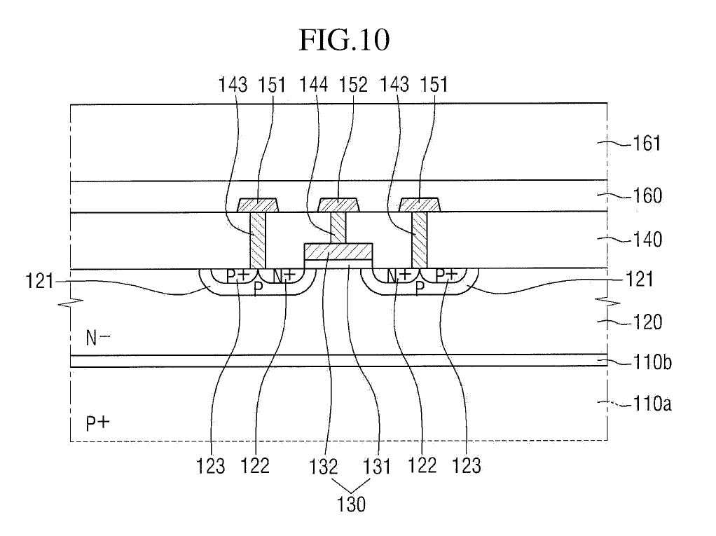

In an exemplary embodiment in accordance with principles of inventive concepts, a portion 110a of substrate 110 may be removed, leaving a portion 110b of the substrate, as illustrated in FIG. 10. Substrate material 110a may be removed, for example, by backgrinding, employing laser grinding and/or mechanical grinding, for example. In an exemplary embodiment in accordance with principles of inventive concepts, the thickness of remaining portion 110b (also referred to herein as “other portion 110b,” or, simply, “other portion) may be approximately 10 μm or less, for example.

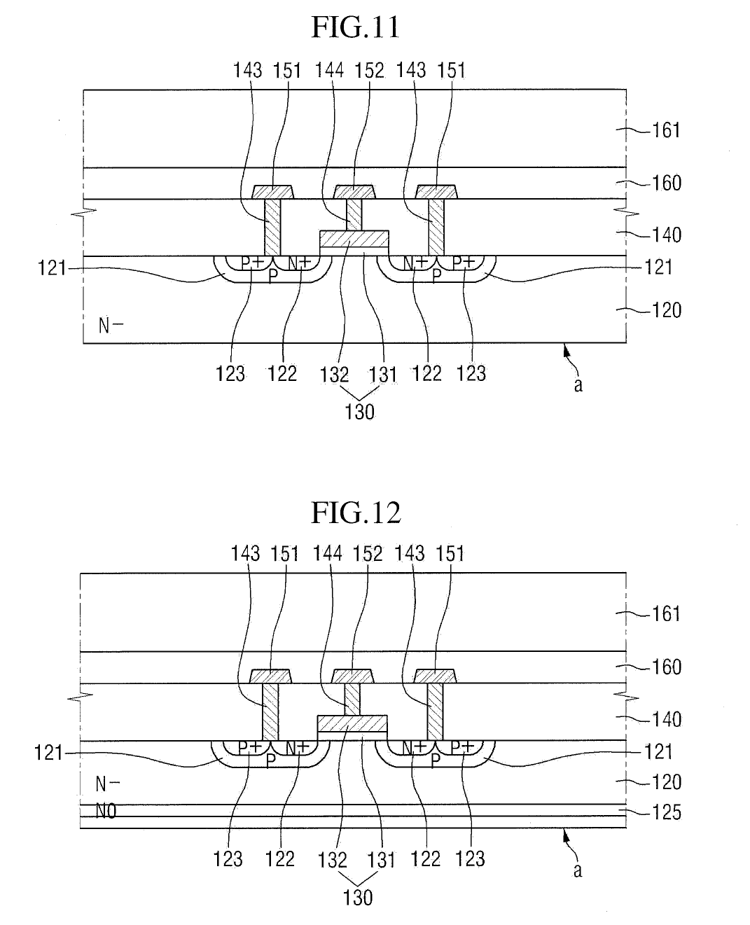

As illustrated in the exemplary embodiment of FIG. 11, the remaining portion 110b of substrate 110 may be removed until the other surface ‘a’ (also referred to herein as “other surface” or “surface ‘a’”) of epitaxial layer 120 is exposed. The remaining portion 110b of substrate 110 may be removed by an etching process, such as wet etching, for example. In an exemplary embodiment in accordance with principles of inventive concepts, an etchant having a high etching rate ratio between substrate 110 and epitaxial layer 120 may be used. For example, an etchant having an etching rate ratio of 20:1, or higher, between substrate 110 and epitaxial layer 120 may be used. In an exemplary embodiment in accordance with principles of inventive concepts, an etchant having an etching rate ratio of 200:1 or higher may be used. Using an etchant with such an etching ratio allows material to be removed from remaining substrate 110b, while leaving epitaxial layer 120 substantially intact. In an exemplary embodiment in accordance with principles of inventive concepts, a mixed solution of F+HNO₃+H₃PO₄+CH₃COOH may be used as an etchant, for example. In embodiments where substrate 110 and the epitaxial layer 120 have different conductivity types, the etch ratio of substrate 110 to epitaxial layer 120 may be higher than when substrate 110 and epitaxial layer 120 have the same conductivity type. The etch ratio of substrate 110 to epitaxial layer 120 may be adjusted depending on a doping density difference between the substrate 110 and the epitaxial layer 120, for example.

When the remaining portion 110b of substrate 110 is removed by etching, it can be precisely reduced to a thickness of 0.1 μm or less, with epitaxial layer 120 serving as an etch stopper. In this manner, substrate 110 may be substantially removed, while maintaining the uniform thickness of epitaxial layer 120. Maintaining the uniform thickness of epitaxial layer 120 avoids the introduction of variations in breakdown voltage characteristics. With substrate 110 completely removed to expose surface ‘a’ of epitaxial layer 120, a thin film IGBT is readily formed.

Although not shown, after remaining portion 110b of substrate 110 is removed, surface ‘a’ of epitaxial layer 120 may be subjected to a chemical mechanical polishing (CMP) process. The CMP process reduces surface roughness of the epitaxial layer 120, which may be due, for example, to non-uniform density of dopants over the surface. In an exemplary embodiment in accordance with principles of inventive concepts, such a polishing process may remove approximately 1 μm from surface ‘a’ of epitaxial layer 120.

Referring to FIG. 12, a buffer layer 125 of a first conductivity type (e.g., N0) may be formed in the epitaxial layer 120. In an exemplary embodiment in accordance with principles of inventive concepts, N-type dopants, such as phosphorous (P) or arsenic (As), may be implanted into surface ‘a’ of epitaxial layer 120 to form buffer layer 125. In an exemplary embodiment in accordance with principles of inventive concepts, P may be implanted with energy in a range of from 70 keV to 1 MeV, and As may be implanted with energy in a range of from 100 keV to 1 MeV. An annealing process may be performed after the implanting of dopants into epitaxial layer 120 to diffuse dopants into epitaxial layer 120.

Buffer layer 125 may increase a breakdown voltage by preventing a punchthrough phenomenon. Buffer layer 125 may be formed at a lower region of the epitaxial layer 120 but not in contact with surface ‘a’ of epitaxial layer 120, for example.

Buffer layer 125 may have the same conductivity type as epitaxial layer 120 and may have a doping density higher than epitaxial layer 120 and lower than source region 122. For example, the dose of buffer layer 125 may be in a range of from 10¹⁵/cm² to 10¹⁶/cm². The formation of buffer layer 125 is optional, and may be left to the discretion of those skilled in the art.

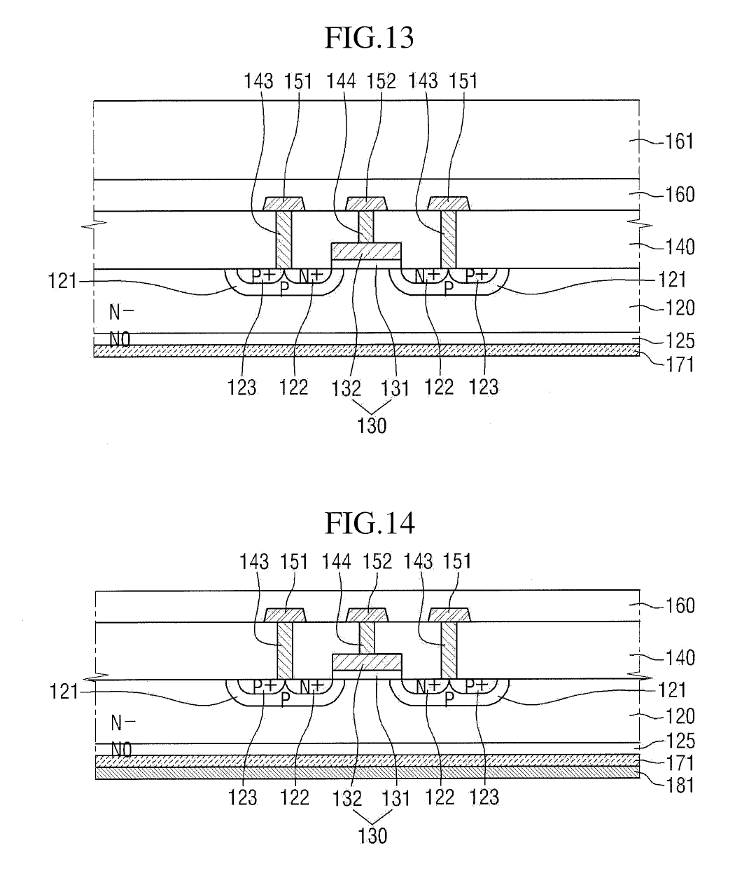

In an exemplary embodiment of FIG. 13, a second conductivity type collector layer 171 is formed in epitaxial layer 120 at surface ‘a’. In an exemplary embodiment in accordance with principles of inventive concepts, collector layer 171 may be formed by implanting P-type dopants such as B, BF₂ or In into epitaxial layer 120 through surface ‘a’. For example, B may be implanted into the epitaxial layer 120 with energy of 100 keV or less, and BF₂ may be implanted into the epitaxial layer 120 with energy of 400 keV or less. In may be implanted into epitaxial layer 120 with energy of 700 keV or less. Collector layer 171 may have a different conductivity type from epitaxial layer 120 and may have a doping density in a range of, for example, from 10¹³/cm² to 10¹⁸/cm². An annealing process may be performed for dopant activation after the implanting of dopants to form collector layer 171. In an exemplary embodiment in accordance with principles of inventive concepts, the annealing process may be performed by rapid thermal annealing (RTA) or laser annealing, for example.

As illustrated in the exemplary embodiment of FIG. 14, a collector electrode 181 may be formed on collector layer 171, after which sustain wafer 161 may be removed. In an exemplary embodiment in accordance with principles of inventive concepts, collector electrode 181 may be formed on collector layer 171 by depositing a conductive layer on collector layer 171 by sputtering or chemical vapor deposition (CVD), for example. Sustain wafer 161 may be etched by an etch back process to expose a top surface of passivation layer 160. In an exemplary embodiment in accordance with principles of inventive concepts, collector electrode 181 may be electrically connected to the collector layer 171.

In operation of an IGBT manufactured according to the exemplary embodiment of inventive concepts as just described, if a voltage higher than a threshold voltage is applied to gate electrode 132, a channel is formed under gate electrode 132 overlapping with body region 121 and electrons are injected into epitaxial layer 120 through the channel. Injected electrons induce holes to be injected into epitaxial layer 120 from collector layer 171. The hole injection causes conductivity modulation, by which the conductivity increases in epitaxial layer 120 by from several tens to several hundreds of times. Reducing the resistance of epitaxial layer 120 in this manner allows the IGBT to be employed in high power applications at high voltages.

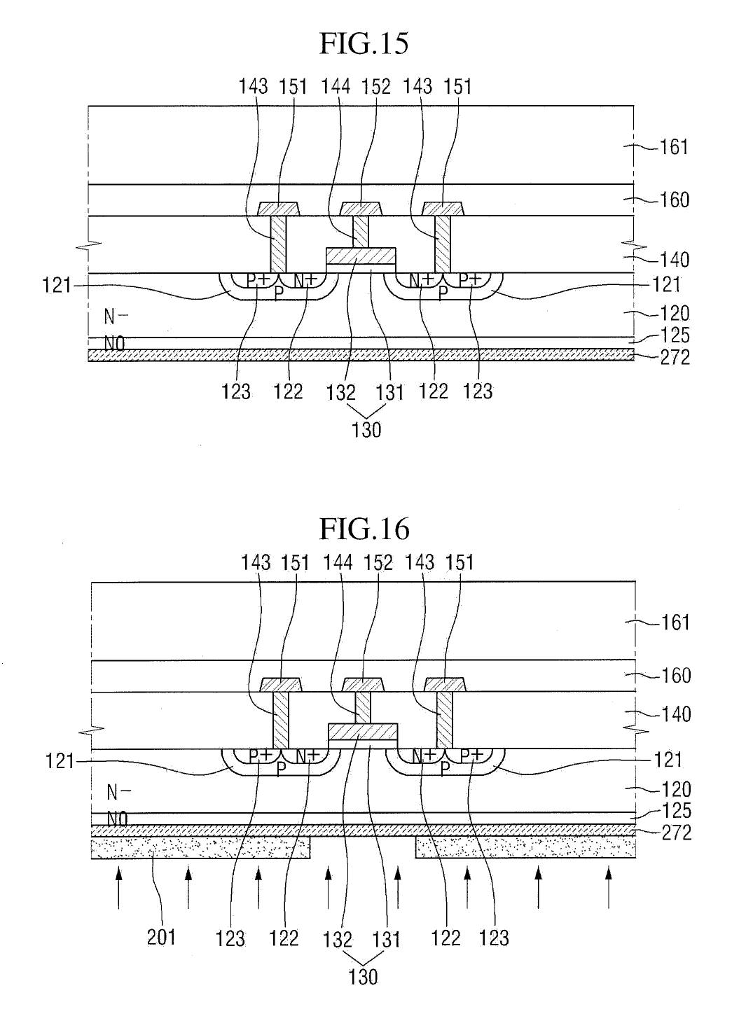

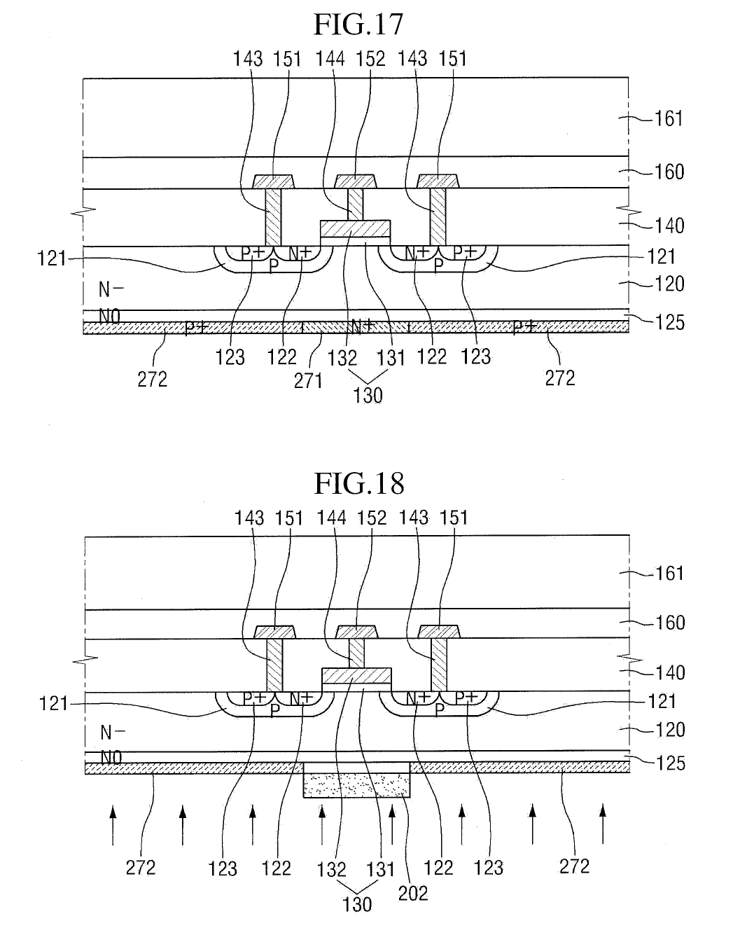

In another exemplary embodiment in accordance with principles of inventive concepts, an IGBT may be manufactured in a method that will be described in reference to FIGS. 15 through 21. The same reference numerals are used to denote substantially the same components as those of the first exemplary embodiment, and detailed descriptions thereof will not be given here. This exemplary embodiment of a manufacturing method of an IGBT (IGBT) is different from the exemplary embodiment just described, primarily in that a first doping region 271 and a second doping region 272 are formed in other surface ‘a’ of epitaxial layer 120.

Referring first to FIGS. 15 through 17, first doping region 271 of a first conductivity type (e.g., N+) and second doping region 272 of a second conductivity type (e.g., P+) may be formed in other surface ‘a’ of epitaxial layer 120. In an exemplary embodiment in accordance with principles of inventive concepts, P-type dopants may be implanted into other surface ‘a’ of epitaxial layer 120 to form second doping region 272. A mask pattern 201 exposing a first doping region 271 may be formed on second doping region 272. N-type dopants may then be implanted into other surface ‘a’ of epitaxial layer 120 and first mask pattern 201 may then be removed to form first doping region 271. In an exemplary embodiment in accordance with principles of inventive concepts, first doping region 271 may be formed to have an area of from 5 to 10% of the total area of first and second doping regions 271, 272. The combination of first and second doping regions 271, 272 of different conductivity types includes a diode which, in combination with the previously-described IGBT, forms an IGBT having an embedded diode.

In an exemplary embodiment in accordance with principles of inventive concepts, first and second doping regions 271, 272 may be formed in a manner that will be described in the discussion related to FIGS. 18 through 20.

In an exemplary embodiment in accordance with principles of inventive concepts of FIG. 18, second doping region 272 may be formed by forming a mask pattern 202 that exposes a region of other surface ‘a’ of epitaxial layer 120, implanting P-type dopants into the exposed region; and then removing the mask pattern 202.

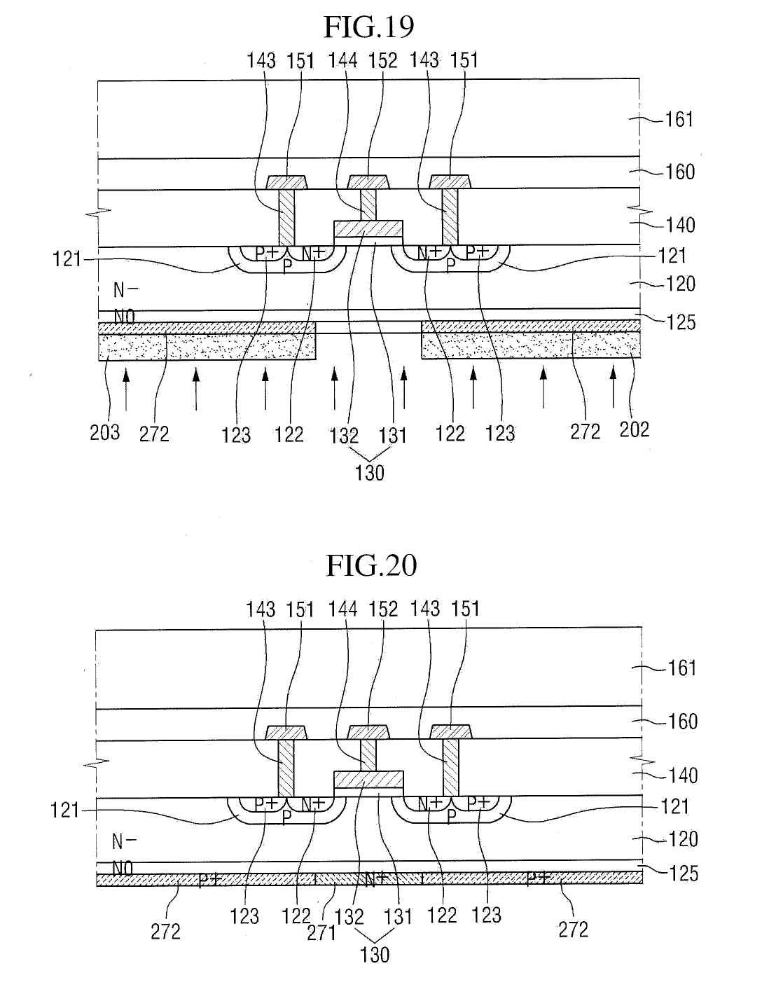

Referring to FIGS. 19 and 20, first doping region 271 may be formed by forming a third mask pattern 203 exposing a region where first doping region 271 is to be formed while blocking the second doping region 272, implanting N-type dopants into other surface ‘a’ of epitaxial layer 120, and then removing third mask pattern 203.

In exemplary embodiments in accordance with principles of inventive concepts, the order of steps shown in FIGS. 18 and 19 may be reversed. That is to say, first doping region 271 may first be formed and second doping region 272 may then be formed.

An annealing process may be performed for dopant activation after implanting dopants to form first doping region 271 and the second doping region 272. In an exemplary embodiment in accordance with principles of inventive concepts, the annealing process may be performed by rapid thermal annealing (RTA) or laser annealing, for example. With second doping region 271 positioned on both sides of first doping region in epitaxial layer 120 an IGBT with embedded diode is formed.

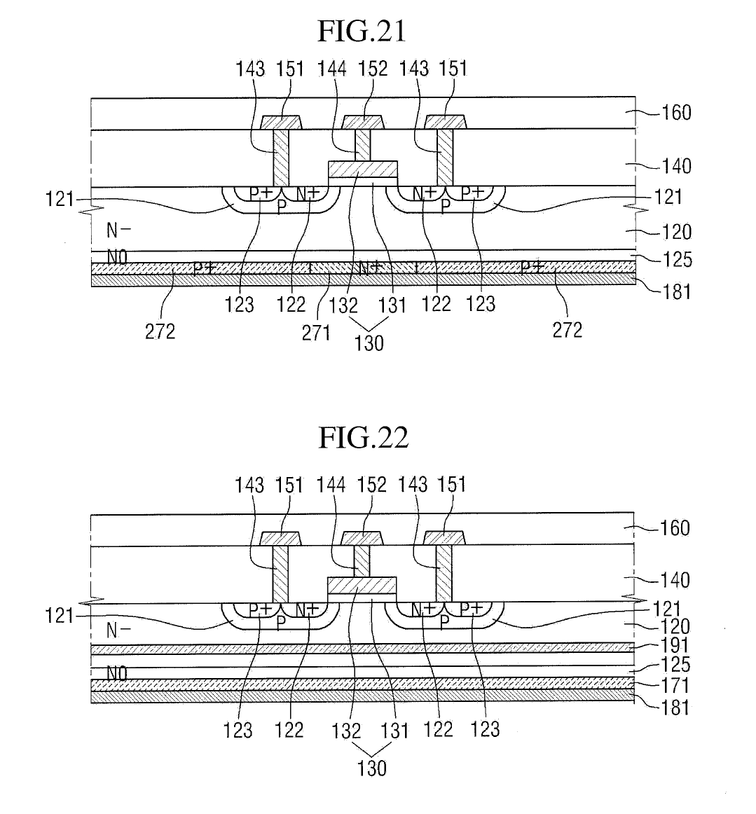

Referring to FIG. 21, a collector electrode 181 may be formed on first and second doping regions 271, 272, followed by removal of sustain wafer 161. The forming of collector electrode 181 and removal of sustain wafer 161 may be performed by the same methods as those of the previous embodiment and detailed descriptions will not be given. The embedded diode formed by first and second doping regions 271, 271 eliminates the need for a separate diode to connect collector electrode 181 to an emitter 123.

A manufacturing method of an IGBT according to a third exemplary embodiment in accordance with principles of inventive concepts will now be described with reference to FIG. 22. The same reference numerals are used to denote substantially the same components as those of the first embodiment, and detailed descriptions thereof will not be given here. FIG. 22 is a cross-sectional view of an IGBT according to a third embodiment of inventive concepts. The manufacturing method of an IGBT (IGBT) according to the third embodiment of inventive concepts may differ from that according to the first embodiment of inventive concepts in that a barrier layer 191 may be formed in an epitaxial layer 120.

Referring to FIG. 22, a barrier layer 191 of a first conductivity type (e.g., N− or N0) may be formed under a body region 121 in epitaxial layer 120. In an exemplary embodiment in accordance with principles of inventive concepts, before forming body region 121, barrier layer 191 may be formed by implanting N-type dopants into a surface of epitaxial layer 120.

Barrier layer 191 provides a potential barrier for holes induced into epitaxial layer 120, thereby accumulating more holes in epitaxial layer 120 and increasing conductivity modulation. In this manner, the resistance of epitaxial layer 120 can be reduced. Barrier layer 191 may be of a first conductivity type that is the same as that of the epitaxial layer 120, for example. In an exemplary embodiment in accordance with principles of inventive concepts, barrier layer 191 may have a doping density higher than epitaxial layer 120. For example, the doping density of barrier layer 191 may be higher than that of epitaxial layer 120 and lower than that of buffer layer 125.

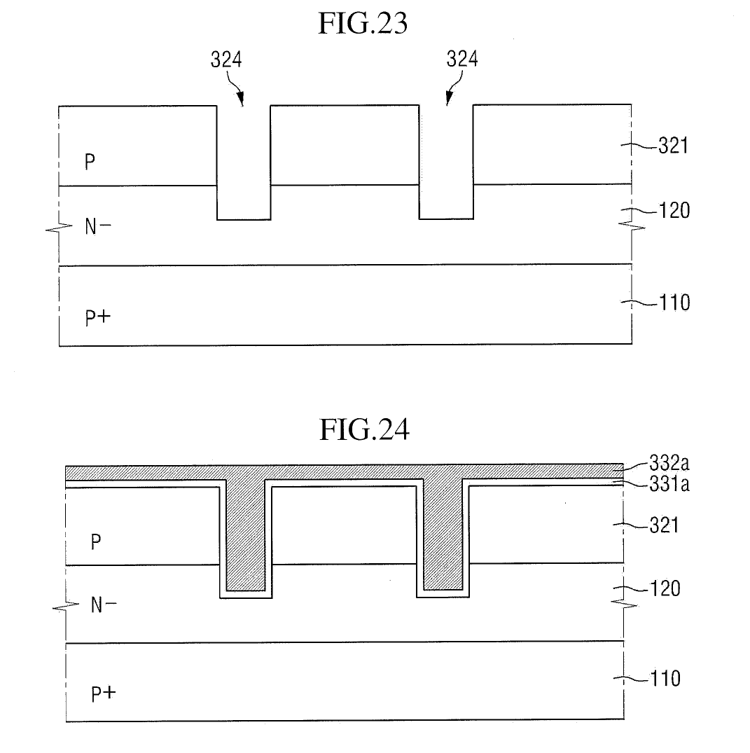

A manufacturing method of an IGBT according to a fourth exemplary embodiment in accordance with principles of inventive concepts will now be described with reference to FIGS. 23 through 29. The same reference numerals are used to denote substantially the same components as those of the first exemplary embodiment, and detailed descriptions thereof will not be given. FIGS. 23 to 29 are cross-sectional views illustrating process steps of a manufacturing method of an IGBT according to a fourth exemplary embodiment in accordance with principles of inventive concepts.

Referring to FIG. 23, an epitaxial layer 120 of a first conductivity type (e.g., N−) may be formed on a substrate 110. A body region 321 of a second conductivity type (e.g., P) may be formed in one surface, also referred to herein as a first surface, of epitaxial layer 120. In an exemplary embodiment in accordance with principles of inventive concepts, body region 321 may be formed by implanting P-type dopants into one surface of epitaxial layer 120. In an exemplary embodiment in accordance with principles of inventive concepts, the dopant implanting may be followed by an annealing process to diffuse the dopants. Although not shown, a mask pattern exposing body region 321 may be formed on one surface of epitaxial layer 120. P-type dopants may then be implanted into the one surface of the epitaxial layer 120 exposed by the mask pattern and the mask pattern may then be removed to form body region 321. In an exemplary embodiment in accordance with principles of inventive concepts, body region 321 may be formed only on a predetermined region of the one surface of the epitaxial layer 120 and body region 321 may be of a second conductivity type that is different from the first conductivity type.

Next, a plurality of trenches 324 penetrating the body region 321 and extending toward the inside of epitaxial layer 120 may be formed. In an exemplary embodiment in accordance with principles of inventive concepts, a mask pattern defining a region where the trenches are to be formed may be formed on body region 321. Areas of body region 321 and epitaxial layer 120 exposed by the mask pattern may then be etched, followed by removal of the mask pattern to form the trenches 324. The etching process may be a dry-etching or wet-etching process.

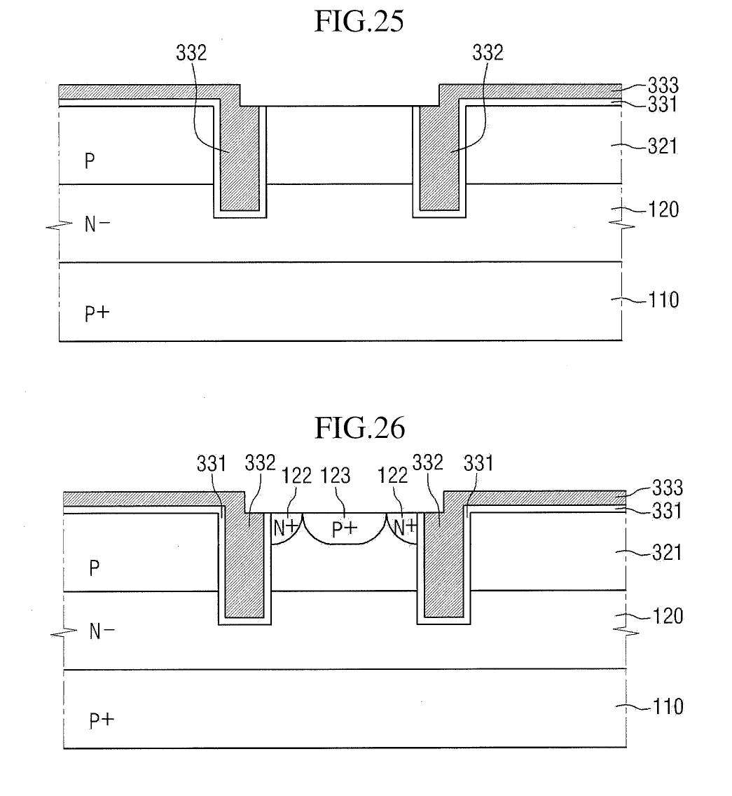

Referring to FIGS. 24 and 25, a gate insulation layer 331 may be formed on internal walls of the trenches 324, and a gate electrode 332 may be formed on gate insulation layer 331.

In an exemplary embodiment in accordance with principles of inventive concepts, an insulation layer 331a for a gate insulation layer may be formed on a top surface of body region 321 and on the inner walls of trenches 324 by CVD, for example. Alternatively, inner walls of trenches 324 or a top surface of body region 321 may be thermally oxidized to form insulation layer 331a. Next, a conductive layer 332a for a gate electrode may be deposited on body region 321 by CVD or sputtering, for example. Trenches 324 may also be filled with conductive layer 332a at this time. Referring to FIG. 25, a mask pattern defining source and emitter regions may be formed on conductive layer 332a. Conductive layer 332a may then be etched in mask-defined regions, followed by removal of the mask pattern. Gate insulation layer 331, gate electrodes 332 and a strapping wire 333 may be thereby defined. Strapping wire 333 may be used to connect gate electrodes 332 between cells in order to thereby reduce resistance. A top surface of body region 321 where the source region and the emitter region are to be formed is also exposed in the etching step. The etching process may be a dry etching process, for example. The thus-formed gate electrodes 332 may be buried in trenches 324.

Additionally, although not shown, insulation layer 331a for a gate insulation layer and conductive layer 332a for gate electrodes may be etched or chemically mechanically polished until the top surface of body region 321 is exposed without using a mask pattern that defines source and emitter regions, thereby forming gate insulation layer 331 and gate electrodes 332.

Referring to FIG. 26, source region 122 of a first conductivity type (e.g., N+) and emitter region 123 of a second conductivity type (e.g., P+) may be formed in body region 321. In an exemplary embodiment in accordance with principles of inventive concepts, a mask pattern defining source region 122 may be formed on one surface of body region 321. N-type dopants may then be implanted into exposed region of the one surface of the body region 321. The mask pattern may then be removed to form source region 122. Next, a mask pattern defining emitter region 123 may be formed on the one surface of body region 321. P-type dopants may then be implanted into the exposed region of the one surface of the body region 321, and the mask pattern may then be removed to form emitter region 123. Emitter region 123 may be formed at one side of source region 122, for example. Although FIG. 26 illustrates an embodiment where two gate electrodes 332 are shared by one emitter region 123, inventive concepts are not limited thereto.

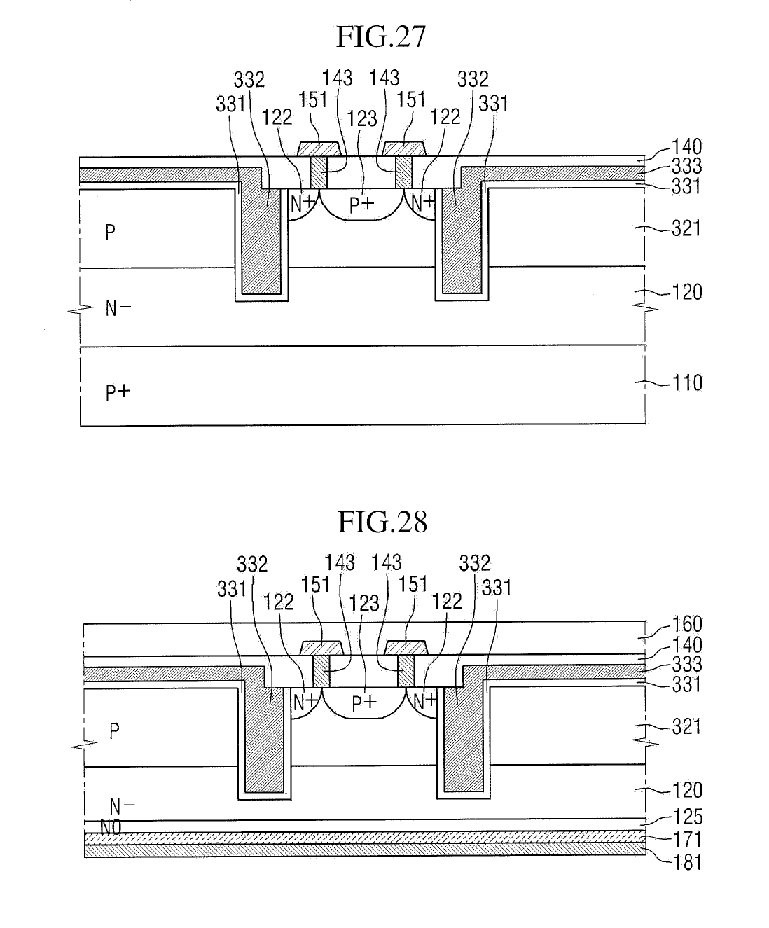

In an exemplary embodiment in accordance with principles of inventive concepts depicted in FIG. 27, an insulation layer 140 may be formed on body region 321, including source region 122 and emitter region 123 and on gate electrodes 332, strapping wire 333, and a first interconnection 151. In an exemplary embodiment in accordance with principles of inventive concepts, an insulating material may be deposited on body region 321 by, for example, CVD, to form insulation layer 140. A mask pattern defining a contact hole may be formed on insulation layer 140 and then insulation layer 140 may be etched using the mask pattern. The mask pattern may then be removed to form a contact hole that exposes predetermined regions of source region 122 and emitter region 123. The predetermined regions of source region 122 and emitter region 123 may be exposed by the same contact hole. Next, the contact hole may be filled with a conductive material to form a first contact 143. A conductive layer may then be deposited on insulation layer 140 and patterned to form first interconnection 151. First interconnection 151 may be electrically connected to source region 122 and emitter region 123 through first contact 143. Therefore, the same voltage may be applied to the source region 122 and the emitter region 123 simultaneously.

Referring to FIG. 28, a passivation layer 160 may be formed on insulation layer 140 and first interconnection 151. A sustain wafer (not shown) may then be formed on passivation layer 160, and the substrate 110 may then be removed to expose the other surface ‘a’ of epitaxial layer 120. Next, a buffer layer 125 of a first conductivity type (e.g., N0) may be formed in epitaxial layer 120, and a collector layer 171 may be formed in the other surface ‘a’ of the epitaxial layer 120. In addition, a collector electrode 181 may be formed in the other surface ‘a’ of epitaxial layer 120. Collector electrode 181 may be electrically connected to collector layer 171. The sustain wafer may be removed after collector layer 171 is formed. The passivation layer 160, the sustain wafer, the buffer layer 125, the collector layer 171 and the collector electrode 181 may be formed by substantially the same methods as those of the first exemplary embodiment and detailed description will not be given here. Substrate 110 may also be removed by substantially the same method as that of the first exemplary embodiment. In an exemplary embodiment in accordance with principles of inventive concepts, a portion of substrate 110 may be removed by back grinding, for example. The remaining portion of substrate 110 may be removed by wet etching, for example. Using the aforementioned method, substrate 110 can be precisely removed while uniformly maintaining the thickness of the epitaxial layer 120. As a result, variation in breakdown characteristic due to non-uniformity in the thickness of epitaxial layer 120 can be minimized. In addition, because substrate 110 may be removed until epitaxial layer 120 is exposed, thin film formation in the IGBT device can be achieved.

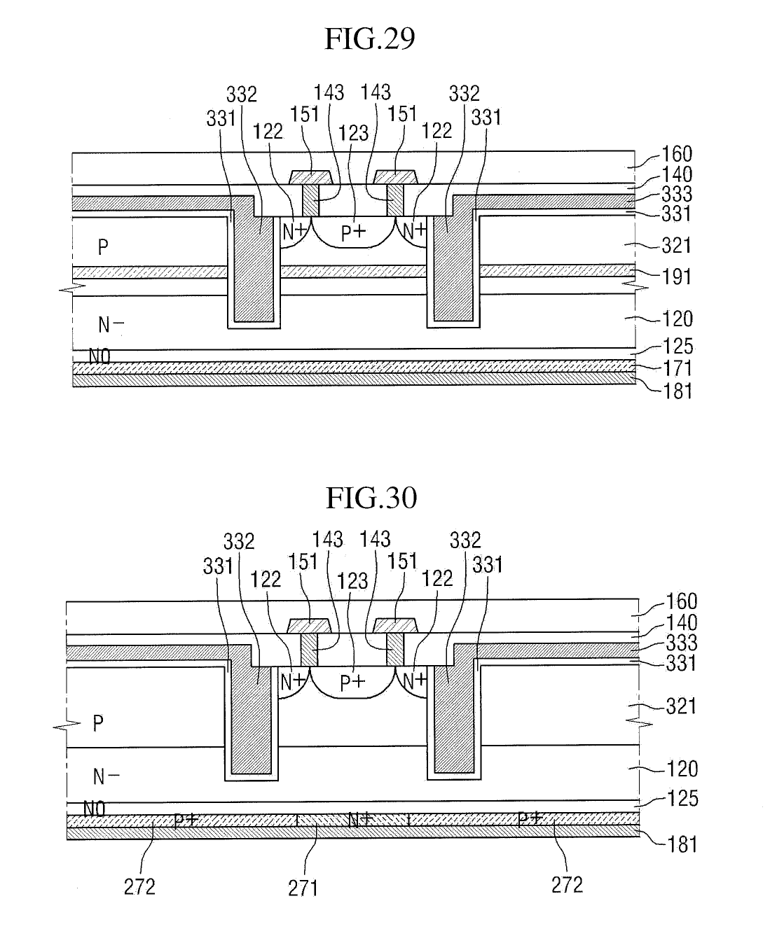

Referring to FIG. 29, the process of manufacturing of an IGBT according principles of inventive concepts may further include the formation of a barrier layer 191 of a first conductivity type (e.g., N− or N0) under a source region 122 before forming trenches 324. In an exemplary embodiment in accordance with principles of inventive concepts, before forming trenches 324, barrier layer 191 may be formed by implanting N-type dopants into one surface of a body region 321, followed by thermally diffusing the dopants, for example.

Barrier layer 191 may be formed in body region 321 or epitaxial layer 120 as long as barrier layer 191 is positioned below source region 122 and source region 122 is positioned above buffer layer 125. Barrier layer 191 may be formed by the same method as in the second exemplary embodiment, for example, and a detailed description thereof will not be given here.

A manufacturing method for forming an IGBT in accordance with principles of inventive concepts according to a fifth exemplary embodiment will be described with reference to FIG. 30. The same reference numerals are used to denote substantially the same components as those of the first exemplary embodiment, and detailed descriptions thereof will not be given here. FIG. 30 is a cross-sectional view of an IGBT according to a fifth exemplary embodiment of inventive concepts. The manufacturing method according to the current embodiment is different from the fourth embodiment, for example, in that a first doping region 271 and a second doping region 272 may be formed in the other surface ‘a’ of an epitaxial layer 120.

Referring to FIG. 30, first doping region 271 of a first conductivity type (e.g., N+) and second doping region 272 of a second conductivity type (e.g., P+) may be formed in the other surface ‘a’ of epitaxial layer 120. In an exemplary embodiment in accordance with principles of inventive concepts, P-type dopants are implanted into other surface ‘a’ of epitaxial layer 120 and a mask pattern defining first doping region 271 is formed on the other surface ‘a’ of epitaxial layer 120. N-type dopants are then implanted in regions exposed by the mask pattern, and the mask pattern is then removed to form first and second doping regions 271, 272. In an exemplary embodiment in accordance with principles of inventive concepts, second doping region 272 may be positioned at both sides of first doping region 271. Alternatively, a mask pattern defining second doping region 272 may be formed on other surface ‘a’ of epitaxial layer 120. Then, P-type dopants may be implanted and the mask pattern removed to form second doping region 272. Next, a mask pattern defining first doping region 271 may be formed on second surface of epitaxial layer 120. Then, N-type dopants may be implanted and the mask pattern removed to form first doping region 271. First doping region 271 and second doping region 272 may be formed by the same methods as those of the second exemplary embodiment and detailed descriptions will not be given here. Because the manufactured IBGT according to this exemplary embodiment has a diode embedded therein, it is not necessary to use a separate diode in connecting collector electrode 181 to an emitter 123.

As described above, in IGBTs manufactured according to principles of inventive concepts, substrate 110 may be completely removed and only epitaxial layer 120 formed on substrate 110 is used, thereby readily enabling thin film formation of IGBTs. Additionally, because the suppression of electron flow associated with a thick substrate 110 may be substantially eliminated, the switching speed of the IGBT may be increased. In addition, because the thickness of the substrate 110 can be delicately adjusted in the course of its removal (that is, at least during an etch step during which a remaining portion of substrate 110b is removed, substrate material may be precisely removed without removing epitaxial material) the thickness of remaining, epitaxial, layer 120 may be kept substantially uniform, thereby maintaining uniformity of breakdown voltage and other device characteristics. In addition, because a diode is embedded in the IGBT, it is not necessary to provide a separate diode.

While inventive concepts have been particularly shown and described with reference to exemplary embodiments thereof, it will be understood by those of ordinary skill in the art that various changes in form and details may be made therein without departing from the spirit and scope of inventive concepts as defined by the following claims. It is therefore desired that the present embodiments be considered in all respects as illustrative and not restrictive, reference being made to the appended claims rather than the foregoing description to indicate the scope of inventive concepts.

What is claimed is:

1. A manufacturing method for an insulated-gate bipolar transistor (IGBT), comprising:
providing a structure including a substrate;
forming a first conductivity type epitaxial layer on the substrate;
forming a gate electrode on a first surface of the epitaxial layer;
forming a second conductivity type body region at opposite sides of the gate electrode in the first surface;
forming a first conductivity type source region within the body region;
removing a portion of the substrate by back grinding; and
removing the other portion of the substrate by etching until a second surface of the epitaxial layer is exposed.

2. The manufacturing method of claim 1, further comprising forming a first conductivity type first doping region and a second conductivity type second doping region within the second surface of the epitaxial layer.

3. The manufacturing method of claim 2, further comprising forming a first conductivity type buffer layer having a higher doping density than the epitaxial layer within the epitaxial layer before forming the first doping region and the second doping region.

4. The manufacturing method of claim 1, further comprising forming a first conductivity type barrier layer having a higher doping density than the epitaxial layer under the body region within the epitaxial layer.

5. The manufacturing method of claim 1, further comprising forming a second conductivity type emitter region within the body region, wherein the emitter region is electrically connected to the same potential as the source region.

6. The manufacturing method of claim 1, wherein the substrate is of a first conductivity type and has a higher doping density than the epitaxial layer.

7. The manufacturing method of claim 1, wherein the substrate is of a second conductivity type.

8. The manufacturing method of claim 1, further comprising:
forming an insulation layer on the body region, the source region, and the gate electrode;
forming a first interconnection connected to the body region and the source region on the insulation layer;
forming a first conductivity type first doping region and a second conductivity type second doping region within the second surface of the epitaxial layer; and
forming a collector electrode on the first doping region and the second doping region.

9. The manufacturing method of claim 1, further comprising:
forming an insulation layer on the body region, the source region, and the gate electrode;
forming a support wafer on the insulation layer; and
removing the support wafer after the removing of the other portion of the substrate before removing the substrate.

10. The manufacturing method of claim 1, further comprising performing chemical mechanical polishing on the second surface of the epitaxial layer after removing the other portion of the substrate.

11. The manufacturing method of claim 1, wherein the providing of the structure comprises:
forming a plurality of trenches penetrating the body region and the source region and extending to the inside of the epitaxial layer;
forming a gate insulation layer on the inner sidewall of each of the trenches; and
forming a gate electrode within each of the trenches.

12. The manufacturing method of claim 1, wherein the etching is performed using an etchant having an etch ratio of the substrate to the epitaxial layer of at least 20:1.

13. A manufacturing method for an IGBT, comprising:
forming a first conductivity type epitaxial layer on a substrate by epitaxial growth;
forming a second conductivity type body region within a first surface of the epitaxial layer;
forming a first conductivity type source region and a second conductivity type emitter region within the body region;
forming a gate electrode on a first surface of the epitaxial layer;
removing the substrate until the second surface of the epitaxial layer is exposed; and
forming a first conductivity type first doping region and a second conductivity type second doping region within the second surface of the epitaxial layer.

14. The manufacturing method of claim 13, wherein the removing of the substrate comprises removing a portion of the substrate by back grinding.

15. The manufacturing method of claim 14, wherein the removing the substrate further comprises removing a remaining portion of the substrate by etching.

16. An insulated-gate bipolar transistor (IGBT), comprising:
an epitaxial layer of a first conductivity type;
an insulated gate electrode formed on a first surface of the epitaxial layer;
body regions of a second conductivity type formed in the first surface of the epitaxial layer on either side of the insulated gate electrode;
source regions of the first conductivity type formed in the body regions adjacent to either side of the insulated gate electrode;
emitter regions of the second conductivity type formed in the body regions opposite source regions from the insulated gate electrode; and
a collector formed on a second surface of the epitaxial layer with no intervening substrate.

17. The IGBT of claim 16 further comprising a buffer layer situated between the collector and the epitaxial layer.

18. The IGBT of claim 16 further comprising a diode structure formed between the collector and the epitaxial layer.

19. The IGBT of claim 18 wherein the diode is implanted in the epitaxial layer.

20. The IGBT of claim 16 wherein the collector is implanted in the epitaxial layer.
